(19) United States
(12) Patent Application Publication
(10) Pub. No.: US 2019/0172931 A1
(43) Pub. Date: Jun. 6, 2019

(54) THIN FILM TRANSISTOR AND MANUFACTURING METHOD THEREOF, ARRAY SUBSTRATE AND DISPLAY PANEL

(71) Applicant: BOE TECHNOLOGY GROUP CO., LTD., Beijing (CN)

(72) Inventor: Xin YANG, Beijing (CN)

(21) Appl. No.: 16/094,149

(22) PCT Filed: Mar. 15, 2018
(86) PCT No.: PCT/CN2018/079128

§ 371 Date: Oct. 16, 2018

(30) Foreign Application Priority Data
Jun. 30, 2017 (CN) 201710526297.9

(51) Int. Cl. H01L 29/66; H01L 21/02; H01L 29/786

(52) U.S. Cl. CPC H01L 29/66757; H01L 21/02532; H01L 21/02592; H01L 27/1222; H01L 21/02675; H01L 21/0262; H01L 29/78675; H01L 21/02573

(57) ABSTRACT

A thin film transistor and a manufacturing method thereof, an array substrate and a display panel are provided, and the manufacturing method includes: forming an amorphous silicon layer on a base substrate, and simultaneously doping a first predetermined element into the amorphous silicon layer; converting the amorphous silicon layer including the first predetermined element into a polysilicon layer which includes a channel region serving as a channel of the thin film transistor, a first region located at a side of the channel region and configured to be connected with a source electrode, and a second region located at another side of the channel region and configured to be connected with a drain electrode; and implanting a second predetermined element into the first region and the second region by an ion implantation process to form a doped source region and a doped drain region, respectively.

This application claims the benefit of Chinese patent application No. 201710526297.9 filed on Jun. 30, 2017, which is hereby entirely incorporated by reference as a part of the present application.

### TECHNICAL FIELD

Embodiments of the present disclosure relate to a thin film transistor, a manufacturing method of the thin film transistor, an array substrate and a display panel.

### BACKGROUND

Flat panel displays (FPD) have become the mainstream products in the display market, and more and more types of the flat panel displays are developed, such as liquid crystal displays (LCDs), organic light emitting diode (OLED) displays, plasma display panels (PDPs), field emission displays (FEDs) and the like.

Thin film transistor (TFT) substrate technology, which is the core technology of the FPD industry, is undergoing profound changes. For example, in the flat panel display, the thin film transistors are used as driving elements, switching elements, or the like.

### SUMMARY

Embodiments of the present disclosure provide a manufacturing method of a thin film transistor. The method includes: forming an amorphous silicon layer on a base substrate and simultaneously doping a first predetermined element into the amorphous silicon layer; converting the amorphous silicon layer comprising the first predetermined element into a polysilicon layer, in which the polysilicon layer comprises a channel region serving as a channel of the thin film transistor, a first region which is located at a side of the channel region and configured to be connected with a source electrode, and a second region which is at another side of the channel region and configured to be connected with a drain electrode; and by an ion implantation process, implanting a second predetermined element into the first region to form a doped source region and implanting the second predetermined element into the second region to form a doped drain region.

For example, the forming the amorphous silicon layer on the base substrate and simultaneously doping the first predetermined element into the amorphous silicon layer comprises: forming the amorphous silicon layer on the base substrate by a chemical vapor deposition, and simultaneously introducing a predetermined gas to dope the first predetermined element into the amorphous silicon layer, in which the predetermined gas comprises the first predetermined element.

For example, the forming the amorphous silicon layer on the base substrate by the chemical vapor deposition and simultaneously introducing the predetermined gas to dope the first predetermined element into the amorphous silicon layer comprises: at a same time of forming the amorphous silicon layer by the chemical vapor deposition using silane and hydrogen, introducing a borane gas to dope element boron into the amorphous silicon layer.

For example, a gas flow ratio of silane to borane is from 50:1 to 100:1.

For example, the forming the amorphous silicon layer on the base substrate by the chemical vapor deposition and simultaneously introducing the predetermined gas to dope the first predetermined element into the amorphous silicon layer comprises: at a same time of forming the amorphous silicon layer by the chemical vapor deposition using silane and hydrogen, introducing a phosphine gas to dope element phosphorus into the amorphous silicon layer.

For example, the forming the amorphous silicon layer on the base substrate by the chemical vapor deposition comprises: forming the amorphous silicon layer on the base substrate by plasma enhanced chemical vapor deposition.

For example, before the implanting the second predetermined element into the first region and the second region by the ion implantation process, the manufacturing method further comprises: performing a patterning process on the polysilicon layer to form a polysilicon active layer, in which the polysilicon active layer comprises the channel region, the first region located at the side of the channel region and configured to be connected with the source electrode, and the second region located at the another side of the channel region and configured to be connected with the drain electrode.

For example, before the implanting the second predetermined element into the first region and the second region by the ion implantation process, the manufacturing method further comprises: sequentially forming a gate insulating layer and a gate electrode on the polysilicon active layer.

For example, by the ion implantation process, the implanting the second predetermined element into the first region to form the doped source region and the implanting the second predetermined element into the second region to form the doped drain region, comprise: by using the gate electrode as a mask, implanting the second predetermined element into the polysilicon active layer by the ion implantation process to form the doped source region at the side of the channel region and the doped drain region at the another side of the channel region, in which an orthographic projection of the channel region on the base substrate overlaps an orthographic projection of the gate electrode on the base substrate.

For example, the converting the amorphous silicon layer comprising the first predetermined element into the polysilicon layer comprises: converting the amorphous silicon layer comprising the first predetermined element into the polysilicon layer by an excimer laser annealing process.

For example, the excimer laser annealing process comprises: performing a plurality of scans on the amorphous silicon layer by using a laser beam to form a plurality of annealing regions, in which the plurality of annealing regions are arranged along a first direction, and each of the plurality of annealing regions extends in a second direction that intersects the first direction; and among the plurality of annealing regions, two annealing regions immediately adjacent to each other in the first direction overlap each other to form an overlap region, and a ratio of an area of the overlap region to an area of the annealing region is a laser annealing coverage.

For example, the excimer laser annealing process comprises: controlling the laser annealing coverage to be from 96% to 99%.

For example, the converting the amorphous silicon layer comprising the first predetermined element into the polysilicon layer by the excimer laser annealing process comprises: controlling a temperature of the base substrate to be from 300° C. to 600° C.

For example, the converting the amorphous silicon layer comprising the first predetermined element into the polysilicon layer by the excimer laser annealing process comprises: controlling a duration of the excimer laser annealing process to be from 1 min to 4 min.

For example, before forming the amorphous silicon layer on the base substrate, the manufacturing method further comprises: forming a buffer layer on the base substrate.

For example, after the implanting the second predetermined element into the first region to form the doped source region and the implanting the second predetermined element into the second region to form the doped drain region by the ion implantation process, the manufacturing method further comprises: sequentially forming an interlayer dielectric layer and a source/drain electrode layer on the gate electrode, in which the source/drain electrode layer comprises the source electrode and the drain electrode, the source electrode is connected with the doped source region through a first via hole which passes through the interlayer dielectric layer and the gate insulating layer, and the drain electrode is connected with the doped drain region through a second via hole which passes through the interlayer dielectric layer and the gate insulating layer.

For example, the first predetermined element and the second predetermined element are doping elements of a same type, and a doping concentration of the second predetermined element is higher than a doping concentration of the first predetermined element.

The embodiments of the present disclosure further provide a thin film transistor, and the thin film transistor is manufactured by using the manufacturing method of the thin film transistor according to the embodiments of the present disclosure.

The embodiments of the present disclosure further provide an array substrate including the thin film transistor provided by the embodiments of the present disclosure.

The embodiments of the present disclosure further provide a display panel including the array substrate provided by the embodiments of the present disclosure.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic structural view of a thin film transistor according to one technique;

FIG. 2 is a flow chart of a manufacturing method of a thin film transistor according to embodiments of the present disclosure;

FIG. 3 is a schematic structural view after forming a polysilicon active layer in the embodiments of the present disclosure;

FIG. 4 is a schematic structural view after forming a gate electrode in the embodiments of the present disclosure;

FIG. 5 is a schematic structural view after forming a doped source region and a doped drain region in the embodiments of the present disclosure;

FIG. 6 is a schematic structural view after forming an interlayer dielectric layer in the embodiments of the present disclosure; and

FIG. 7 is a schematic structural view after forming a source electrode and a drain electrode in the embodiments of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but includes an electrical connection, directly or indirectly. “On,” “under,” “right,” “left” and the like are only used to indicate relative position relationship, and when the position of the object which is described is changed, the relative position relationship is changed accordingly.

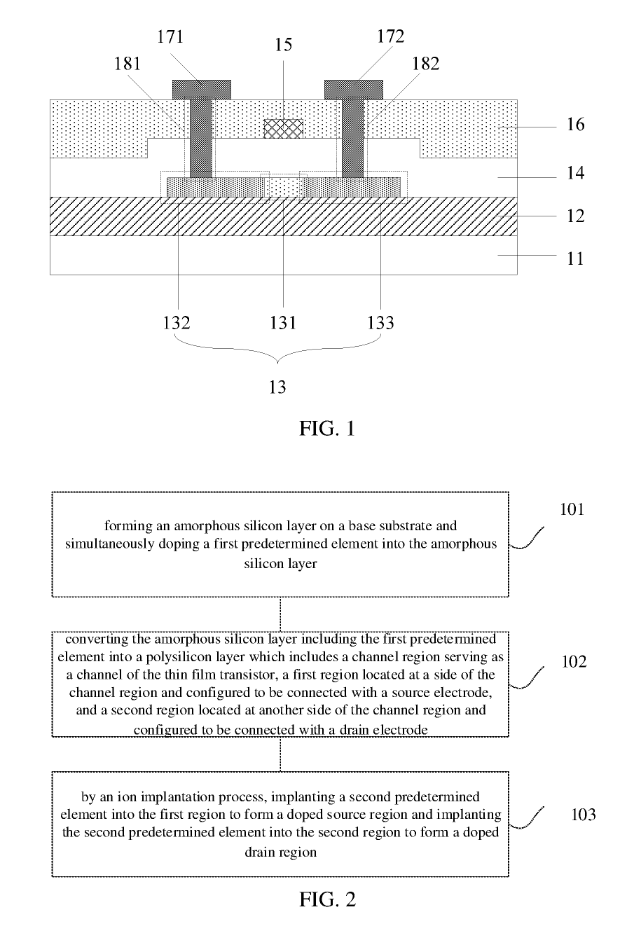

FIG. 1 is a schematic structural view of a low temperature polysilicon thin film transistor according to one technique. The thin film transistor includes: a buffer layer 12 disposed on a base substrate 11, a polysilicon active layer 13 (including a channel region 131, a doped source region 132 at a side of the channel region 131 and a doped drain region 133 at another side of the channel region 131) disposed on the buffer layer 12, a gate insulating layer 14 disposed on the active layer, a gate electrode 15 disposed on the gate insulating layer 14, an interlayer dielectric layer 16 disposed on the gate electrode 15, and a source electrode 171 and a drain electrode 172 which are disposed on the interlayer dielectric layer 16. The source electrode 171 is connected with the doped source region 132 through a first via hole 181, and the drain electrode 172 is connected with the doped drain region 133 through a second via hole 182. For example, for the thin film transistor of the above-described structure, the method of forming the polysilicon active layer is as follows. First, an amorphous silicon layer is formed, the amorphous silicon layer is converted into a polysilicon layer by laser annealing, then a first ion implantation is performed on the polysilicon layer so that the entire polysilicon layer is lightly doped, and then the two sides of the channel region are doped heavily by a second ion implantation process to form the doped source region at the side of the channel region and the doped drain region at another side of the channel region. However, in such method of forming the channel region, the doped source region and the doped drain region of the active layer, the ion implantation process is needed to lightly dope the channel region, and the manufacturing process is complicated; furthermore, in a situation where the channel region of the active layer is lightly doped via the ion implantation process, the lattice structure of the channel region of the polysilicon active layer is damaged, so that the channel region of the active layer formed is defective, resulting in defects of the formed thin film transistor such as current leakage.

Referring to FIG. 2, embodiments of the present disclosure provide a manufacturing method of a thin film transistor, and the method includes the following steps.

Step 101: forming an amorphous silicon layer on a base substrate and simultaneously doping a first predetermined element into the amorphous silicon layer.

For example, the forming the amorphous silicon layer on the base substrate and simultaneously doping the first predetermined element into the amorphous silicon layer includes: forming the amorphous silicon layer on the base substrate by a chemical vapor deposition, and simultaneously introducing a predetermined gas to dope the first predetermined element into the amorphous silicon layer, with the predetermined gas containing the first predetermined element. For example, the amorphous silicon layer is formed on the base substrate by a plasma enhanced chemical vapor deposition (PECVD) method.

For example, the amorphous silicon layer is formed by silane (SiH₄) and hydrogen (H₂); and as for the doping of the first predetermined element, the doping is achieved by introducing the predetermined gas containing the first predetermined element. For example, in the case that an element boron is needed to be doped into the amorphous silicon layer, a borane gas is introduced into the device into which the silane and the hydrogen are introduced to form the amorphous silicon layer, so as to realize forming the amorphous silicon layer and simultaneously doping the element boron into the amorphous silicon layer. For example, in the case that an element phosphorus is to be doped into the amorphous silicon layer, a phosphine gas is introduced into the device into which the silane and the hydrogen are introduced to form the amorphous silicon layer, so as to realize forming the amorphous silicon layer and simultaneously doping the element phosphorus into the amorphous silicon layer. For example, the first predetermined element is an impurity element that is doped into the polysilicon active layer to enhance the electrical conductivity of the channel region of the polysilicon thin film transistor. For example, for a p-channel thin film transistor, a third main group element, for example, a boron element, is doped into the active layer; and for an n-channel thin film transistor, a fifth main group element, for example, a phosphorus element, is doped into the active layer.

For example, the ratio between the introduced gases of silane and borane is controlled to control the doping amount of boron, and the ratio between the introduced gases of silane and phosphine is controlled to control the doping amount of phosphorus, thereby forming polysilicon having desired doping amounts. For example, a gas flow ratio of silane to borane is controlled to be from 50:1 to 100:1 so as to form the boron doped polysilicon layer with high quality.

Step 102: converting the amorphous silicon layer including the first predetermined element into a polysilicon layer which includes a channel region serving as the channel of the thin film transistor, a first region located at a side of the channel region and configured to be connected with a source electrode, and a second region located at another side of the channel region and configured to be connected with a drain electrode. In this step, the first region is a region where a doped source region is to be formed, and the second region is a region where a doped drain region is to be formed.

For example, before the step 102, the method of the embodiments of the present disclosure further includes: performing a surface treatment on the amorphous silicon layer to facilitate subsequent processes. For example, the surface treatment is performed on the amorphous silicon layer by hydrofluoric acid cleaning, ozone cleaning, or the like.

For example, the amorphous silicon layer is converted into the polysilicon layer by an excimer laser annealing process.

For example, in a situation where the first predetermined element is doped into the amorphous silicon layer, doping atoms in the amorphous silicon layer may act as crystal nuclei during the crystallization process of converting the amorphous silicon layer into the polysilicon layer; thus, in the crystallization process, along with the increase of the amount of the doping atoms, the nucleation rate increases, resulting in a decrease in the sizes of the polysilicon grains and a slight increase in the grain boundaries, which affects the quality of the polysilicon layer.

For example, in order to avoid the defect of poor quality of the polysilicon layer, in the embodiments of the present disclosure, the crystallization process of converting the amorphous silicon layer into the polysilicon layer by the excimer laser annealing process is prolonged by controlling a laser annealing coverage, so that the polysilicon layer of high quality is formed. For example, in the embodiments of the present disclosure, the laser annealing coverage is controlled to be 96%-99%, and further, for example, 96%-97%, to form the polysilicon layer of high quality. The light spot of the laser beam used in the laser annealing process is very small and is far less than the area of the amorphous silicon layer to be annealed; therefore, the laser beam needs to scan the amorphous silicon layer for a plurality of times during annealing the amorphous silicon layer by the laser annealing, so as to complete the annealing of the entire amorphous silicon layer. For example, the laser beam scans the amorphous silicon layer for the plurality of times to form a plurality of annealing regions (for example, each of the plurality of times of scanning the amorphous silicon layer forms one annealing region to obtain a plurality of annealing regions, and areas of the plurality of annealing regions are equal to each other), and the plurality of annealing regions are arranged (ranked) along a first direction, and each of the plurality of annealing regions extends in a second direction intersecting the first direction; two annealing regions immediately adjacent to each other in the first direction overlap each other to form an overlap region, and the ratio of the area of the overlap region to the area of the annealing region (i.e. one of the plurality of annealing regions) is the laser annealing coverage. For example, the laser annealing coverage is controlled by adjusting the parameters of a laser annealing apparatus.

For example, in order to avoid the defect of poor quality of the polysilicon layer, in the embodiments of the present disclosure, the crystallization process of converting the amorphous silicon layer into the polysilicon layer by the excimer laser annealing process is prolonged by increasing the temperature of the base substrate, so as to reduce the nucleation rate of polysilicon and improve the quality of the polysilicon layer. For example, during converting the amorphous silicon layer into the polysilicon layer by the excimer laser annealing process, the temperature of the base substrate is from 300° C. to 600° C.

For example, in order to avoid the defect of poor quality of the polysilicon layer, in the embodiments of the present disclosure, during the crystallization process of converting the amorphous silicon layer into the polysilicon layer by the excimer laser annealing process, an annealing time is prolonged by slowing the scanning speed of the laser beam, thereby prolonging the crystallization process to form the polysilicon layer of high quality. For example, in the embodiments of the present disclosure, the annealing time of the laser annealing process is from 1 min to 4 min.

Step 103: by an ion implantation process, implanting a second predetermined element into the first region to form a doped source region and implanting the second predetermined element into the second region to form a doped drain region.

For example, the first predetermined element and the second predetermined element are doping elements of a same type. For example, the first predetermined element and the second predetermined element are both p-type doping elements. For example, the first predetermined element and the second predetermined element are both n-type doping elements.

For example, a doping concentration of the second predetermined element is higher than a doping concentration of the first predetermined element.

For example, before implanting the second predetermined element into the first region and the second region by the ion implantation process, the manufacturing method further includes: patterning the polysilicon layer to form a polysilicon active layer which includes the channel region, the first region located at the side of the channel region and configured to be connected with the source electrode, and the second region located at the another side of the channel region and configured to be connected with the drain electrode. Further, before implanting the second predetermined element into the first region and the second region by the ion implantation process, the manufacturing method further includes: sequentially forming a gate insulating layer and a gate electrode on the polysilicon active layer. For example, the step of sequentially forming the gate insulating layer and the gate electrode on the polysilicon active layer is after the step of patterning the polysilicon layer to form the polysilicon active layer. That is, the polysilicon layer is first patterned to form the polysilicon active layer; then, the gate insulating layer and the gate electrode are sequentially formed on the polysilicon active layer; afterwards, the first region and the second region are implanted with the second predetermined element by the ion implantation process.

For example, the implanting the second predetermined element into the first region to form the doped source region and implanting the second predetermined region into the second region to form the doped drain region by the ion implantation process includes: by adopting the gate electrode as a mask, implanting the second predetermined element into the polysilicon active layer by the ion implantation process to form the doped source region at the side of the channel region and the doped drain region at the another side of the channel region. For example, an orthographic projection of the channel region on the base substrate overlaps an orthographic projection of the gate electrode on the base substrate.

For example, the polysilicon layer is patterned to form the polysilicon active layer, and then ion implantation is performed to form the doped source region and the doped drain region; or, the polysilicon layer is ion implanted to form the doped source electrode in a partial region and the doped drain region in another partial region, and then is patterned to form the polysilicon active layer. In the embodiments of the present disclosure, after the polysilicon layer is patterned to form the polysilicon active layer, the doped source region and the doped drain region are formed by performing the ion implantation process on the polysilicon active layer; and before the doped source region and the doped drain region are formed by performing the ion implantation process on the polysilicon active layer, the gate insulating layer and the gate electrode are sequentially formed on the polysilicon active layer, so that the gate electrode is used as the mask to form the doped source region and the doped drain region, which simplifies the processes. Of course, it is also possible that the gate electrode is not used as the mask; for example, by forming a patterned photoresist as a mask, two sides of the channel region are doped to form the doped source region and the doped drain region.

In the embodiments of the present disclosure, the first predetermined element is doped at the same time of forming the amorphous silicon layer, so that an ion implantation process of implanting the first predetermined element to lightly dope the channel region of the active layer is avoided, and the manufacturing process of the thin film transistor is simplified. It is further possible to avoid that the ion implantation process damages the channel region of the polysilicon layer, and thus improve the film quality of the channel region of the active layer, and reduce the leakage current of the thin film transistor.

For example, with respect to the step 101, before forming the amorphous silicon layer on the base substrate, the manufacturing method of the embodiments of the present disclosure further includes: forming a buffer layer on the base substrate.

For example, with respect to the step 103, after implanting the second predetermined element into the first region to form the doped source region and implanting the second predetermined element into the second region to form the doped drain region by the ion implantation process, the manufacturing method further includes: sequentially forming an interlayer dielectric layer and a source/drain electrode layer on the gate electrode, the source/drain electrode layer includes the source electrode and the drain electrode, the source electrode is connected with the doped source region through a first via hole in the interlayer dielectric layer and the gate insulating layer, and the drain electrode is connected with the doped drain region through a second via hole in the interlayer dielectric layer and the gate insulating layer.

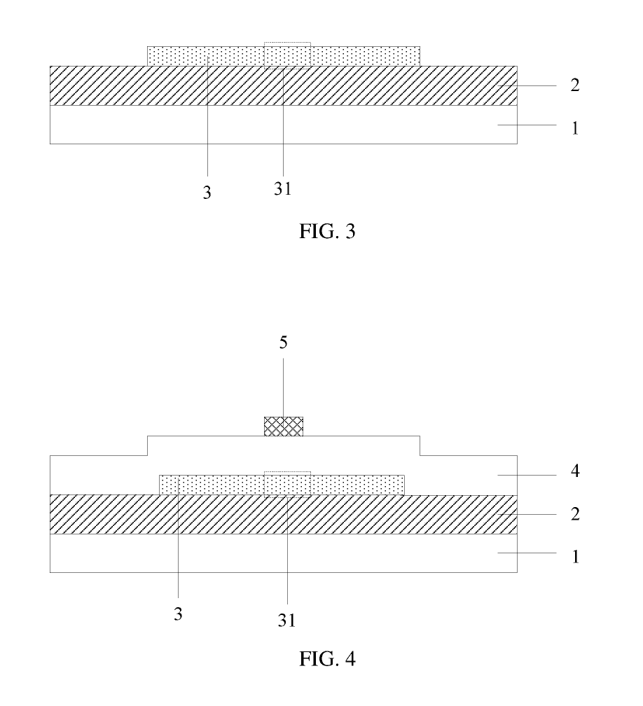

In order to explain the manufacturing method of the thin film transistor provided by the embodiments of the present disclosure in more detail, the following is exemplified in conjunction with FIG. 3 to FIG. 7.

The manufacturing method of a low temperature polysilicon thin film transistor provided by the embodiments of the present disclosure includes the following steps.

In step one, a buffer layer is deposited on a base substrate by plasma enhanced chemical vapor deposition (PECVD) method. For example, the base substrate is a glass substrate.

In step two, by the PECVD method, using a mixed gas of silane, hydrogen and borane as a reaction gas, in which the gas flow rate of the silane is 200 sccm, the gas flow rate of the hydrogen is 750 sccm and the flow rate of the borane is 4 sccm, and using a radio frequency power of 150 W, a working pressure of 290 Pa and a temperature of 390° C., a boron-doped amorphous silicon layer is formed on the buffer layer. For example, the specific radio frequency power, working pressure and reaction temperature are not limited to this condition, and may be adjusted according to actual needs.

In step three, the amorphous silicon layer is converted into a polysilicon layer by an excimer laser annealing process, and a polysilicon active layer is formed by a patterning process performed on the polysilicon layer. A schematic structural view after forming the buffer layer 2 and the polysilicon active layer 3 on the base substrate 1 is shown in FIG. 3, in which the polysilicon active layer 3 includes a channel region 31, and a first region and a second region respectively at two sides of the channel region 31.

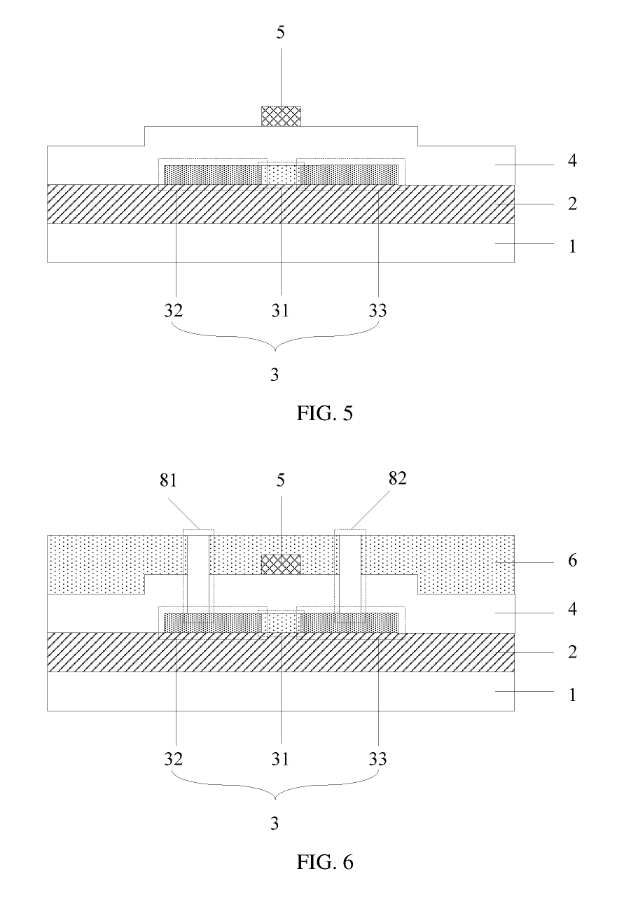

In step four, a gate insulating layer 4 is deposited on the polysilicon active layer 3, a gate metal film is deposited on the gate insulating layer 4, and a gate electrode 5 is formed by a patterning process performed on the gate metal film, and an orthographic projection of the gate electrode 5 on the base substrate 1 overlaps the orthographic projection of the channel region 31 on the base substrate 1. A schematic structural view after the gate electrode 5 is formed is shown in FIG. 4.

In step five, using the gate electrode 5 as a mask, the polysilicon active layer 3 is heavily doped by an ion implantation process to form a doped source region 32 at a side of the channel region 31 and a doped drain region 33 at another side of the channel region 31. A schematic structural view after the doped source region and the doped drain region are formed is shown in FIG. 5.

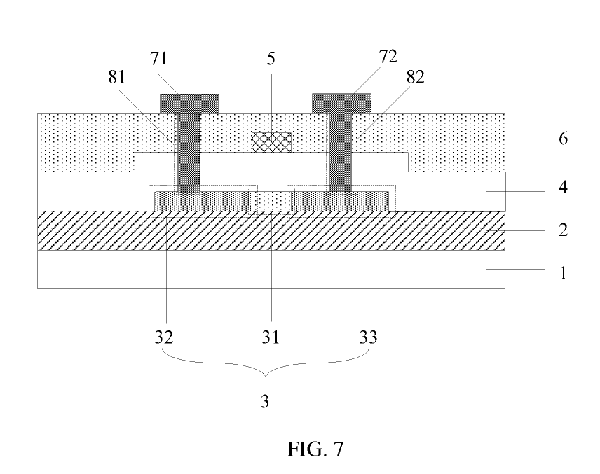

In step six, an interlayer dielectric layer 6 is deposited on the gate electrode 5, and a patterning process is performed to form a first via hole 81 exposing a portion of the doped source region 32 and a second via hole 82 exposing a portion of the doped drain region 33. A schematic structural view after the interlayer dielectric layer is formed is shown in FIG. 6.

In step seven, a source/drain electrode layer including a source electrode 71 and a drain electrode 72 is formed on the interlayer dielectric layer 6, the source electrode 71 is in contact with the doped source region 32 through the first via hole 81, and the drain electrode 72 is in contact with the doped drain region 33 through the second via hole 82. A schematic structural view after the source electrode and the drain electrode are formed is shown in FIG. 7. So far, the thin film transistor is obtained.

Referring to FIG. 7, the embodiments of the present disclosure further provide a thin film transistor prepared by the manufacturing method of the thin film transistor according to the embodiments of the present disclosure. The thin film transistor includes:

the polysilicon active layer 3 on the base substrate 1, in which the polysilicon active layer 3 includes the channel region 31, the doped source region 32 at the side of the channel region 31, and the doped drain region 33 at the another side of the channel region 31.

For example, the thin film transistor further includes the following components:

the buffer layer 2 between the base substrate 1 and the active layer 3;

the gate insulating layer 4 on the polysilicon active layer 3;

the gate electrode 5 on the gate insulating layer 4;

the interlayer dielectric layer 6 on the gate electrode 5; and

the source/drain electrode layer on the interlayer dielectric layer 6, in which the source/drain electrode layer includes the source electrode 71 and the drain electrode 72, the source electrode 71 is in contact with the doped source region 32 through the first via hole 81, and the drain electrode 72 is in contact with the doped drain region 33 through the second via hole 82.

The embodiments of the present disclosure further provide an array substrate including the thin film transistor provided by the embodiments of the present disclosure.

The embodiments of the present disclosure further provide a display panel including the array substrate provided by the embodiments of the present disclosure.

The embodiments of the present disclosure further provide a display device including the display panel provided by the embodiments of the present disclosure.

For example, in the embodiments of the present disclosure, the first predetermined element is doped at the same time of forming the amorphous silicon layer, so that the ion implantation process of implanting the first predetermined element for lightly doping the channel region is avoided, the manufacturing process of the thin film transistor is simplified, the damage to the polysilicon layer in the channel region by the ion implantation process is avoided, the film quality of the channel region of the active layer is improved, and the leakage current of the thin film transistor is reduced.

The foregoing embodiments merely are exemplary embodiments of the disclosure, and not intended to define the scope of the disclosure, and the scope of the disclosure is determined by the appended claims.

1. A manufacturing method of a thin film transistor, comprising:
forming an amorphous silicon layer on a base substrate and simultaneously doping a first predetermined element into the amorphous silicon layer;
converting the amorphous silicon layer comprising the first predetermined element into a polysilicon layer, wherein the polysilicon layer comprises a channel region serving as a channel of the thin film transistor, a first region which is located at a side of the channel region and configured to be connected with a source electrode, and a second region which is at another side of the channel region and configured to be connected with a drain electrode; and
by an ion implantation process, implanting a second predetermined element into the first region to form a doped source region and implanting the second predetermined element into the second region to form a doped drain region.

2. The manufacturing method according to claim 1, wherein the forming the amorphous silicon layer on the base substrate and simultaneously doping the first predetermined element into the amorphous silicon layer comprises:
forming the amorphous silicon layer on the base substrate by a chemical vapor deposition, and simultaneously introducing a predetermined gas to dope the first predetermined element into the amorphous silicon layer, wherein the predetermined gas comprises the first predetermined element.

3. The manufacturing method according to claim 2, wherein the forming the amorphous silicon layer on the base substrate by the chemical vapor deposition and simultaneously introducing the predetermined gas to dope the first predetermined element into the amorphous silicon layer comprises:
at a same time of forming the amorphous silicon layer by the chemical vapor deposition using silane and hydrogen, introducing a borane gas to dope element boron into the amorphous silicon layer.

4. The manufacturing method according to claim 3, wherein a gas flow ratio of silane to borane is from 50:1 to 100:1.

5. The manufacturing method according to claim 2, wherein the forming the amorphous silicon layer on the base substrate by the chemical vapor deposition and simultaneously introducing the predetermined gas to dope the first predetermined element into the amorphous silicon layer comprises:
at a same time of forming the amorphous silicon layer by the chemical vapor deposition using silane and hydrogen, introducing a phosphine gas to dope element phosphorus into the amorphous silicon layer.

6. The manufacturing method according to claim 2, wherein the forming the amorphous silicon layer on the base substrate by the chemical vapor deposition comprises:
forming the amorphous silicon layer on the base substrate by plasma enhanced chemical vapor deposition.

7. The manufacturing method according to claim 1, wherein before the implanting the second predetermined element into the first region and the second region by the ion implantation process, the manufacturing method further comprises:
performing a patterning process on the polysilicon layer to form a polysilicon active layer, wherein the polysilicon active layer comprises the channel region, the first region located at the side of the channel region and configured to be connected with the source electrode, and the second region located at the another side of the channel region and configured to be connected with the drain electrode.

8. The manufacturing method according to claim 7, wherein before the implanting the second predetermined element into the first region and the second region by the ion implantation process, the manufacturing method further comprises:
sequentially forming a gate insulating layer and a gate electrode on the polysilicon active layer.

9. The manufacturing method according to claim 8, wherein by the ion implantation process, the implanting the second predetermined element into the first region to form the doped source region and the implanting the second predetermined element into the second region to form the doped drain region, comprise:
by using the gate electrode as a mask, implanting the second predetermined element into the polysilicon active layer by the ion implantation process to form the doped source region at the side of the channel region and the doped drain region at the another side of the channel region, wherein an orthographic projection of the channel region on the base substrate overlaps an orthographic projection of the gate electrode on the base substrate.

10. The manufacturing method according to claim 1, wherein the converting the amorphous silicon layer comprising the first predetermined element into the polysilicon layer comprises:
converting the amorphous silicon layer comprising the first predetermined element into the polysilicon layer by an excimer laser annealing process.

11. The manufacturing method according to claim 10, wherein
the excimer laser annealing process comprises: performing a plurality of scans on the amorphous silicon layer by using a laser beam to form a plurality of annealing regions, wherein the plurality of annealing regions are arranged along a first direction, and each of the plurality of annealing regions extends in a second direction that intersects the first direction; and
among the plurality of annealing regions, two annealing regions immediately adjacent to each other in the first direction overlap each other to form an overlap region, and a ratio of an area of the overlap region to an area of the annealing region is a laser annealing coverage.

12. The manufacturing method according to claim 11, wherein the excimer laser annealing process comprises: controlling the laser annealing coverage to be from 96% to 99%.

13. The manufacturing method according to claim 1, wherein the converting the amorphous silicon layer comprising the first predetermined element into the polysilicon layer by the excimer laser annealing process comprises: controlling a temperature of the base substrate to be from 300 C to 600° C.

14. The manufacturing method according to claim 10, wherein the converting the amorphous silicon layer comprising the first predetermined element into the polysilicon layer by the excimer laser annealing process comprises: controlling a duration of the excimer laser annealing process to be from 1 min to 4 min.

15. The manufacturing method according to claim 1, wherein before forming the amorphous silicon layer on the base substrate, the manufacturing method further comprises: forming a buffer layer on the base substrate.

16. The manufacturing method according to claim 8, wherein after the implanting the second predetermined element into the first region to form the doped source region and the implanting the second predetermined element into the second region to form the doped drain region by the ion implantation process, the manufacturing method further comprises:
sequentially forming an interlayer dielectric layer and a source/drain electrode layer on the gate electrode, wherein the source/drain electrode layer comprises the source electrode and the drain electrode, the source electrode is connected with the doped source region through a first via hole which passes through the interlayer dielectric layer and the gate insulating layer, and the drain electrode is connected with the doped drain region through a second via hole which passes through the interlayer dielectric layer and the gate insulating layer.

17. The manufacturing method according to claim 1, wherein the first predetermined element and the second predetermined element are doping elements of a same type, and a doping concentration of the second predetermined element is higher than a doping concentration of the first predetermined element.

18. A thin film transistor, wherein the thin film transistor is manufactured by using the manufacturing method according to claim 1.

19. An array substrate, comprising the thin film transistor according to claim 18.

20. A display panel, comprising the array substrate according to claim 19.
